(19) United States
(12) Patent Application Publication
(10) Pub. No.: US 2026/0282840 A1
(43) Pub. Date: Sep. 17, 2026

(54) MEMBER FOR SEMICONDUCTOR MANUFACTURING APPARATUS

(71) Applicant: NGK Corporation, Nagoya-shi (JP)

(72) Inventors: Seiya INOUE, Nishio-city (JP); Tatsuya KUNO, Nagoya-city (JP)

(21) Appl. No.: 19/670,457

(22) Filed: May 7, 2026

Related U.S. Application Data
(63) Continuation of application No. PCT/JP2025/032842, filed on Sep. 18, 2025.

(30) Foreign Application Priority Data
Nov. 13, 2024 (JP) 2024-198269

(51) Int. Cl. H10P 72/76

(52) U.S. Cl. CPC H10P 72/7624; H10P 72/7611; H10P 72/7616

(57) ABSTRACT

A wafer placement table includes: a ceramic plate incorporating an electrode; a base plate incorporating a refrigerant flow path; a through hole penetrating the base plate; an insulating tube inserted into the through hole; a power feeding member inserted into the insulating tube and having a tip electrically connected to the electrode; and an adhesive layer having a first adhesive portion provided in a first gap between the insulating tube and the through hole and a second adhesive portion provided in a second gap between the insulating tube and the power feeding member. A lower surface of the power feeding member is located below a bottom surface of the refrigerant flow path. At least one of a lower surface of the first adhesive portion or a lower surface of the second adhesive portion is located at the same height as, or above, the bottom surface of the refrigerant flow path.

### CROSS-REFERENCE TO RELATED APPLICATION

This application is a continuation application of PCT/JP2025/032842, filed on September 18, 2025, which claims the benefit of priority of Japanese Patent Application No. 2024-198269 filed on November 13, 2024, the entire contents of which are incorporated herein by reference.

### BACKGROUND OF THE INVENTION

### Field of the Invention

The present invention relates to a member for semiconductor manufacturing apparatus.

### Description of the Related Art

Conventionally, a member for semiconductor manufacturing apparatus for processing a wafer placed on a wafer placement surface has been known. For example, the member for semiconductor manufacturing apparatus described in PTL 1 includes an electrostatic chuck sheet having a wafer placement surface on its upper surface and incorporating an electrode, an aluminum susceptor bonded to a lower surface of the electrostatic chuck sheet, a through hole penetrating the susceptor in an up-down direction, an insulating tube inserted into the through hole, and a rod-shaped power feeding member inserted into the insulating tube and having an upper end electrically connected to the electrode. An adhesive layer is filled in the entirety of a gap between the insulating tube and the through hole and the entirety of a gap between the insulating tube and the power feeding member.

### CITATION LIST

### Patent Literature

PTL 1: JP H07-161803A

### SUMMARY OF THE INVENTION

However, when the member for semiconductor manufacturing apparatus is used in a high-temperature process or a high-power process, if the adhesive layer is filled in the entirety of the gap between the insulating tube and the through hole and the entirety of the gap between the insulating tube and the power feeding member as in PTL 1, a problem may arise in the connection between the power feeding member and the electrode.

The present invention has been made to solve such a problem, and a primary object thereof is to suppress occurrence of a problem in the connection between the power feeding member and the electrode.

[1] A member for semiconductor manufacturing apparatus of the present invention includes: a ceramic plate having a wafer placement surface on its upper surface and incorporating an electrode; a base plate provided on a lower surface of the ceramic plate and incorporating a refrigerant flow path; a base-plate through hole penetrating the base plate in an up-down direction at a position offset from a center of the base plate; an insulating tube inserted into the base-plate through hole; a power feeding member inserted into the insulating tube and having a tip electrically connected to the electrode; and an adhesive layer having a first adhesive portion provided in a first gap between the insulating tube and the base-plate through hole and a second adhesive portion provided in a second gap between the insulating tube and the power feeding member, wherein a lower surface of the power feeding member is located below a bottom surface of the refrigerant flow path, and at least one of a lower surface of the first adhesive portion or a lower surface of the second adhesive portion is located at the same height as, or above, the bottom surface of the refrigerant flow path.

In this member for semiconductor manufacturing apparatus, when heat is input from the wafer placement surface side, the member for semiconductor manufacturing apparatus deforms so as to be convex upward. The manner of deformation at this time differs between an upper side and a lower side with a plane including the bottom surface of the refrigerant flow path as a boundary. In the present invention, at least one of the lower surface of the first adhesive portion or the lower surface of the second adhesive portion is located at the same height as, or above, the bottom surface of the refrigerant flow path. Accordingly, even if the manner of deformation of the member for semiconductor manufacturing apparatus differs between the upper side and the lower side with the plane including the bottom surface of the refrigerant flow path as a boundary, it is possible to suppress occurrence of a problem in the connection between the power feeding member and the electrode due to the influence thereof.

In the present specification, the invention may be described using terms such as up-down, left-right, and front-back; however, these directions are merely relative positional relationships. Therefore, when the orientation of the member for semiconductor manufacturing apparatus is changed, the up-down direction may become down-up, or may become left-right or front-back; such cases are also included in the technical scope of the present invention.

[2] In the member for semiconductor manufacturing apparatus (the member for semiconductor manufacturing apparatus described in [1] above), an absolute value of a difference in coefficient of thermal expansion between the ceramic plate and the base plate at 40 to 570° C may be 1.0 ppm/K or less. This can suppress occurrence of a problem in the connection between the power feeding member and the electrode due to a difference in thermal expansion between the ceramic plate and the base plate.

[3] In the member for semiconductor manufacturing apparatus (the member for semiconductor manufacturing apparatus described in [1] or [2] above), the lower surface of the first adhesive portion and the lower surface of the second adhesive portion may both be located at the same height as, or below, a ceiling surface of the refrigerant flow path. This enables heat at a position immediately above the baseplate through hole to be efficiently transferred to the refrigerant in the refrigerant flow path via the first and second adhesive portions, thereby improving temperature uniformity of the wafer.

[4] In the member for semiconductor manufacturing apparatus (the member for semiconductor manufacturing apparatus described in any one of [1] to [3] above), the lower surface of the first adhesive portion and the lower surface of the second adhesive portion may both be located at the same height as, or above, the bottom surface of the refrigerant flow path. This can further suppress occurrence of a problem in the connection between the power feeding member and the electrode even if an amount of deformation of the member for semiconductor manufacturing apparatus differs between above and below the bottom surface of the refrigerant flow path.

[5] In the member for semiconductor manufacturing apparatus (the member for semiconductor manufacturing apparatus described in any one of [1] to [4] above), in a plan view, an area of the first gap may be smaller than an area of the second gap. This facilitates forming a structure in which the lower surface of the second adhesive portion is located above the lower surface of the first adhesive portion.

[6] In the member for semiconductor manufacturing apparatus (the member for semiconductor manufacturing apparatus described in any one of [1] to [5] above), the lower surface of the power feeding member may include a connector connectable to a tip end of an external cable and may be located above a lower surface of the insulating tube, and the lower surface of the second adhesive portion may be located above the lower surface of the power feeding member. This makes it difficult for the second adhesive portion to adhere to the connector on the lower surface of the power feeding member.

[7] In the member for semiconductor manufacturing apparatus (the member for semiconductor manufacturing apparatus described in any one of [1] to [6] above), a thermal conductivity of the base plate may be 50W/mK or more. This enables heat of the wafer to be efficiently transferred to the refrigerant in the refrigerant flow path via the base plate, thereby improving temperature uniformity of the wafer.

[8] In the member for semiconductor manufacturing apparatus (the member for semiconductor manufacturing apparatus described in any one of [1] to [7] above), a thermal conductivity of the adhesive layer may be 0.5W/mK or more. This enables heat at a position immediately above the base-plate through hole to be efficiently transferred to the refrigerant in the refrigerant flow path via the first and second adhesive portions, thereby improving temperature uniformity of the wafer.

[9] In the member for semiconductor manufacturing apparatus (the member for semiconductor manufacturing apparatus described in any one of [1] to [8] above), a cross-sectional area of the refrigerant flow path may be smaller in a peripheral region of the baseplate through hole than in a region deviating from the peripheral region of the baseplate through hole. This increases a flow velocity of the refrigerant flowing through the peripheral region of the baseplate through hole in the refrigerant flow path. Accordingly, heat at a position immediately above the baseplate through hole is efficiently transferred to the refrigerant in the refrigerant flow path, thereby improving temperature uniformity of the wafer. In reducing the cross-sectional area of the refrigerant flow path, for example, when the cross section of the refrigerant flow path is rectangular, a width (a length in a horizontal direction) of the rectangle may be shortened, or a height (a length in the up-down direction) of the rectangle may be shortened.

[10] In the member for semiconductor manufacturing apparatus (the member for semiconductor manufacturing apparatus described in any one of [1] to [9] above), a distance from the wafer placement surface to a ceiling surface of the refrigerant flow path may be shorter in the peripheral region of the baseplate through hole than in the region deviating from the peripheral region of the baseplate through hole. This enables heat at a position immediately above the baseplate through hole to be efficiently transferred to the refrigerant in the refrigerant flow path, thereby improving temperature uniformity of the wafer.

### BRIEF DESCRIPTION OF THE DRAWINGS

FIG. 1 is a plan view of a wafer placement table 10.

FIG. 2 is a cross-sectional view taken along line A-A of FIG. 1.

FIG. 3 is a partially enlarged view of FIG. 2.

FIG. 4 is a cross-sectional view taken along line B-B of FIG. 3.

FIGS. 5A to 5C are explanatory views showing an adhesion step of an insulating tube 50 of the present embodiment.

FIG. 6 is a partially enlarged longitudinal sectional view of a wafer placement table 910 (comparative embodiment).

FIG. 7 is a partially enlarged longitudinal sectional view of another embodiment.

FIG. 8 is a partially enlarged longitudinal sectional view of another embodiment.

FIG. 9 is a partially enlarged longitudinal sectional view of another embodiment.

FIG. 10 is a longitudinal sectional view of another embodiment.

FIG. 11 is a longitudinal sectional view of another embodiment.

FIG. 12 is a longitudinal sectional view of another embodiment.

### DETAILED DESCRIPTION OF THE INVENTION

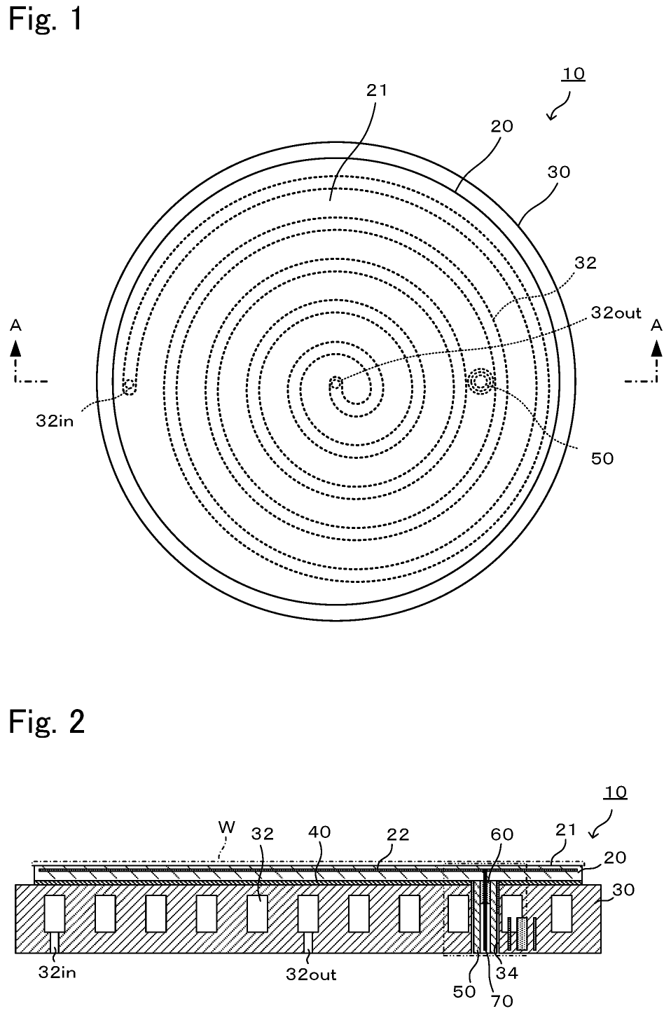

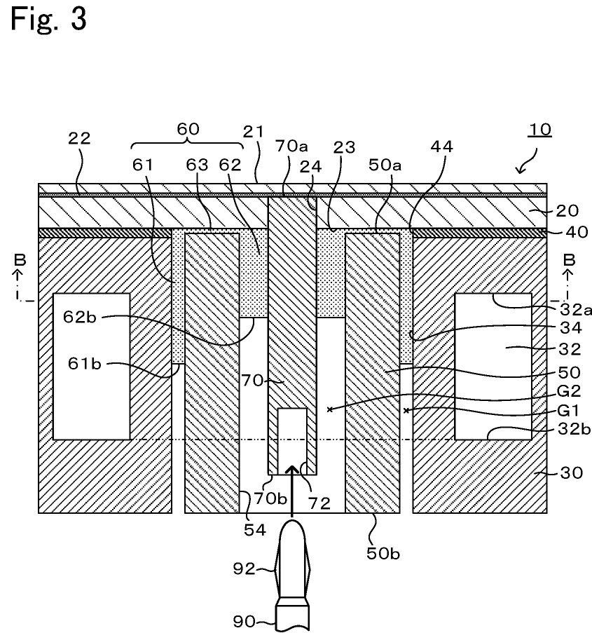

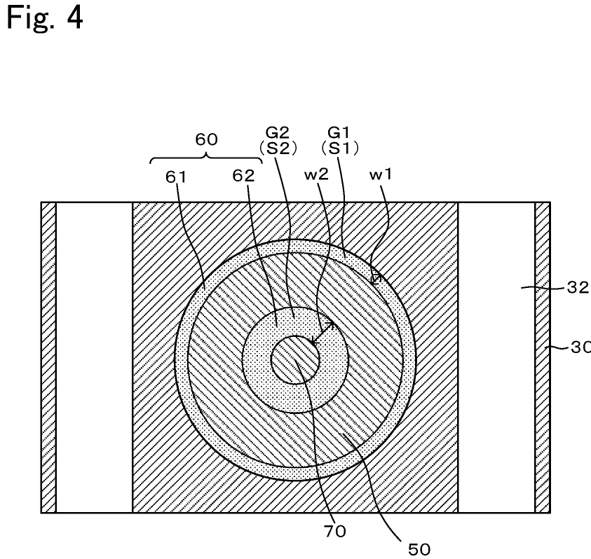

Preferred embodiments of the present invention will be described with reference to the drawings. FIG. 1 is a plan view of a wafer placement table 10, FIG. 2 is a cross-sectional view taken along line A-A of FIG. 1, FIG. 3 is a partially enlarged view of FIG. 2 (an enlarged view within a frame indicated by a two-dot chain line), and FIG. 4 is a cross-sectional view taken along line B-B of FIG. 3.

The wafer placement table 10 is an example of the member for semiconductor manufacturing apparatus of the present invention and, as shown in FIG. 2, includes a ceramic plate 20, a base plate 30, a bonding layer 40, a baseplate through hole 34, an insulating tube 50, an adhesive layer 60, and a power feeding member 70.

The ceramic plate 20 is a ceramic disk (for example, having a diameter of 300mm and a thickness of 5mm) made of, for example, a sintered alumina body or a sintered aluminum nitride body. An upper surface of the ceramic plate 20 is a wafer placement surface 21 on which a wafer W is placed. The ceramic plate 20 incorporates an electrostatic electrode 22. Although not shown, an annular seal band is formed along an outer edge on the wafer placement surface 21 of the ceramic plate 20, and a plurality of circular small projections are formed on an entire surface inside the seal band. The electrostatic electrode 22 is a planar mesh electrode and is connected to an external DC power supply (not shown) via the power feeding member 70. When a DC voltage is applied to the electrostatic electrode 22, the wafer W is attracted and fixed to the wafer placement surface 21 by an electrostatic attractive force, and when application of the DC voltage is stopped, the attraction and fixing of the wafer W to the wafer placement surface 21 is released.

The base plate 30 is a disk having good electrical conductivity and thermal conductivity (for example, a disk having the same diameter as, or a larger diameter than, the ceramic plate 20 and having a thickness of 25mm). In the base plate 30, a refrigerant flow path 32 through which a refrigerant circulates is formed. The refrigerant flowing through the refrigerant flow path 32 is preferably a liquid and is preferably electrically insulative. Examples of the electrically insulative liquid include a fluorine-based inert liquid. As shown in FIG. 1, the refrigerant flow path 32 is formed in a spiral shape in a one-stroke pattern from one end (an inlet 32in) to the other end (an outlet 32out) over the entirety of the base plate 30 in a plan view. A supply port and a recovery port of an external refrigerant device (not shown) are connected to the inlet 32in and the outlet 32out of the refrigerant flow path 32, respectively. The refrigerant supplied from the supply port of the external refrigerant device to the inlet 32in of the refrigerant flow path 32 passes through the refrigerant flow path 32, returns from the outlet 32out of the refrigerant flow path 32 to the recovery port of the external refrigerant device, and, after temperature adjustment, is supplied again from the supply port to the inlet 32in of the refrigerant flow. path 32. The base plate 30 is connected to a high-frequency (RF) power supply and is also used as an RF electrode.

Examples of a material of the base plate 30 include a metal material and a composite material of metal and ceramic. Examples of the metal material include Al, Ti, Mo, or alloys thereof. Examples of the composite material of metal and ceramic include a metal matrix composite (MMC) and a ceramic matrix composite (CMC). Specific examples of such composite materials include a material containing Si, SiC, and Ti (also referred to as SiSiCTi), a material obtained by impregnating a porous SiC body with Al and/or Si, and a composite material of Al₂O₃ and TiC. As the material of the base plate 30, it is preferable to select a material having a coefficient of thermal expansion (CTE) close to that of the material of the ceramic plate 20.

The absolute value of the difference in CTE between the ceramic plate 20 and the base plate 30 at 40 to 570° C is preferably 1.0ppm/K or less. For example, when the ceramic plate 20 is made of alumina (CTE at 40 to 570° C: 7.0 to 8.0ppm/K), the base plate 30 is preferably made of AlSiC (SiC 75%) (CTE at 40 to 570° C: 7.0 to 9.0ppm/K) or SiSiCTi (CTE at 40 to 570° C: preferably 7.5 to 8.0ppm/K). When the ceramic plate 20 is made of aluminum nitride (CTE at 40 to 570° C: 4.0 to 5.0ppm/K), the base plate 30 is preferably made of Mo (CTE at 40 to 570° C: 5.0 to 6.0ppm/K). The thermal conductivity of the base plate 30 is preferably 50W/mK or more. Examples of the material having a thermal conductivity of 50W/mK or more include the above-mentioned AlSiC (SiC 75%), AlSiC (SiC 85%), and SiSiCTi.

Here, the bonding layer 40 is a metal layer, and bonds a lower surface of the ceramic plate 20 and an upper surface of the base plate 30. The metal layer can be formed by known TCB (Thermal Compression Bonding) using a metal bonding material (for example, an Al-Mg-based bonding material or an Al-Si-Mg-based bonding material).

The baseplate through hole 34 is a substantially cylindrical hole penetrating the base plate 30 in the up down direction and is provided at a position offset from the center of the base plate 30 so as not to penetrate the refrigerant flow path 32. The baseplate through hole 34 communicates with a bonding-layer through hole 44. The bonding-layer through hole 44 is a substantially cylindrical hole penetrating the bonding layer 40 in the up-down direction and is provided at a position facing the baseplate through hole 34. An opening edge of the baseplate through hole 34 may be chamfered.

The insulating tube 50 is housed in the baseplate through hole 34 and the bonding-layer through hole 44. The insulating tube 50 is a substantially cylindrical member made of an electrically insulating material (for example, ceramic or resin) and has an insulating-tube through hole 54 penetrating the insulating tube 50 in the up-down direction along a central axis of the insulating tube 50. A first gap G1 is formed between an outer peripheral surface of the insulating tube 50 and an inner peripheral surface of the baseplate through hole 34. A second gap G2 is formed between an inner peripheral surface of the insulating tube 50 and an outer peripheral surface of the power feeding member 70. The insulating tube 50 is fixed to the base-plate through hole 34 by the adhesive layer 60. As shown in FIG. 4, in a plan view, an area S1 of the ring-shaped first gap G1 is smaller than an area S2 of the ring-shaped second gap G2. Further, a width w1 (a length in a radial direction) of the first gap G1 is smaller than a width w2 of the second gap G2.

The power feeding member 70 is a metal rod and is inserted into the insulating-tube through hole 54 of the insulating tube 50. The power feeding member 70 includes a socket portion 72 on a lower surface 70b. Examples of the metal used for the power feeding member 70 include W, Mo, and Ni, and a metal having a coefficient of thermal expansion close to that of the ceramic plate 20 is preferable. The socket portion 72 is a connector connectable to a tip end of an external cable 90. The external cable 90 is connected to a DC power supply for electrostatic attraction (not shown). In the present embodiment, the socket portion 72 allows insertion and removal of a plug 92 provided at a tip end of the external cable 90. For example, the socket portion 72 may be a banana socket and the plug 92 may be a banana plug. The lower surface 70b of the power feeding member 70 is located below a bottom surface 32b of the refrigerant flow path 32 and above a lower surface 50b of the insulating tube 50. An upper surface 70a of the power feeding member 70 is electrically connected, by a brazing material or the like, to the electrostatic electrode 22 exposed at a hole bottom of a ceramic-plate bottomed hole 24. The ceramic-plate bottomed hole 24 is a substantially cylindrical hole provided from a lower surface 23 of the ceramic plate 20 to the electrostatic electrode 22 and has a smaller diameter than the insulating-tube through hole 54. The power feeding member 70 is electrically insulated from the base plate 30 by the insulating tube 50.

The adhesive layer 60 includes a first adhesive portion 61, a second adhesive portion 62, and a third adhesive portion 63. An upper surface of the adhesive layer 60 (an upper surface of the first adhesive portion 61, an upper surface of the second adhesive portion 62, and an upper surface of the third adhesive portion 63) is in contact with the lower surface 23 of the ceramic plate 20. The first adhesive portion 61 is provided in the first gap G1. A lower surface 61b of the first adhesive portion 61 is located above the bottom surface 32b of the refrigerant flow path 32 and below a ceiling surface 32a of the refrigerant flow path 32. The second adhesive portion 62 is provided in the second gap G2. A lower surface 62b of the second adhesive portion 62 is located above the bottom surface 32b of the refrigerant flow path 32 and below the ceiling surface 32a of the refrigerant flow path 32. The lower surface 61b of the first adhesive portion 61 is located below the lower surface 62b of the second adhesive portion 62. The third adhesive portion 63 is provided in a slight gap between an upper surface 50a of the insulating tube 50 and the lower surface 23 of the ceramic plate 20. The third adhesive portion 63 may be omitted. In that case, the upper surface 50a of the insulating tube 50 and the lower surface 23 of the ceramic plate 20 are in contact with each other. Examples of a material of the adhesive layer 60 include insulating resins such as an epoxy resin, an acrylic resin, and a silicone resin. The adhesive layer 60 may be obtained by adding a filler to an insulating resin. The filler preferably has a higher thermal conductivity than the insulating resin of the adhesive layer 60, and may be, for example, alumina or aluminum nitride. The thermal conductivity of the adhesive layer 60 is preferably 0.5W/mK or more. For example, a silicone resin containing an alumina filler (thermal conductivity: 2.2W/mK) may be used as the adhesive layer 60. For example, the ceiling surface 32a of the refrigerant flow path 32 is formed at a position 1 to 8mm from the lower surface of the bonding layer 40, preferably at a position 2 to 6mm therefrom. Further, for example, a distance from the ceiling surface 32a of the refrigerant flow path 32 to the bottom surface 32b of the refrigerant flow path 32 may be 5 to 15mm.

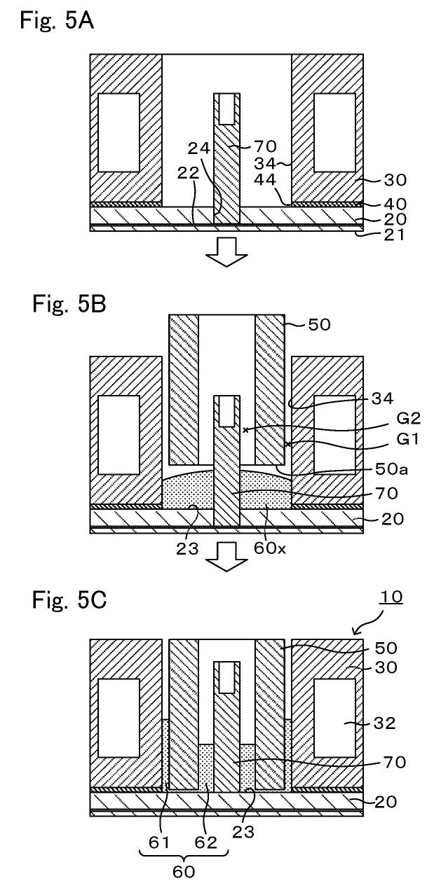

Next, of a method for manufacturing the wafer placement table 10, a step of bonding the insulating tube 50 will be described with reference to FIGS. 5A to 5C. FIGS. 5A to 5C are explanatory views of this step. In FIGS. 5A to 5C, the wafer placement surface 21 of the ceramic plate 20 faces downward. FIGS. 5A to 5C are partially enlarged views in which a peripheral portion around the base-plate through hole 34 is enlarged.

First, a bonded body is prepared in which the ceramic plate 20 and the base plate 30 are joined by the bonding layer 40 (FIG. 5A). In this bonded body, the electrostatic electrode 22 is embedded in the ceramic plate 20. Further, in this bonded body, the power feeding member 70 is disposed in the baseplate through hole 34 and the bonding-layer through hole 44 and is inserted through the ceramic-plate bottomed hole 24 and is electrically connected to the electrostatic electrode 22. Next, an adhesive 60x is placed on the lower surface 23 of the ceramic plate 20 (FIG. 5B). Then, the insulating tube 50 is inserted into the baseplate through hole 34 such that the upper surface 50a of the insulating tube 50 faces the adhesive 60x. Subsequently, when the insulating tube 50 is pushed toward the ceramic plate 20, the adhesive 60x climbs up in the first gap G1 between the inner peripheral surface of the baseplate through hole 34 and the outer peripheral surface of the insulating tube 50, and in the second gap G2 between the outer peripheral surface of the power feeding member 70 and the inner peripheral surface of the insulating tube 50. Further, when the insulating tube 50 is pushed toward the ceramic plate 20, the gap between the lower surface 23 of the ceramic plate 20 and the upper surface 50a of the insulating tube 50 becomes narrower. Here, the width w1 of the first gap G1 is smaller than the width w2 of the second gap G2, and in a plan view, the area S1 of the first gap G1 is smaller than the area S2 of the second gap G2 (see FIG. 4). Therefore, the height by which the adhesive 60x climbs up in the first gap G1 becomes higher than the height by which the adhesive 60x climbs up in the second gap G2. These heights are determined by an amount of the adhesive 60x. In this state, by solidifying the adhesive 60x, the insulating tube 50 is bonded to the ceramic plate 20, the base plate 30, and the power feeding member 70 via the adhesive layer 60 having the first adhesive portion 61 and the second adhesive portion 62. Thus, the wafer placement table 10 is obtained (FIG. 5C).

Next, an example of use of the wafer placement table 10 configured as described above will be described. First, with the wafer placement table 10 installed in a chamber (not shown), the wafer W is placed on the wafer placement surface 21. Then, the chamber is depressurized by a vacuum pump and adjusted to a predetermined degree of vacuum, and a DC voltage is applied to the electrostatic electrode 22 of the ceramic plate 20 to generate an electrostatic attractive force, thereby attracting and fixing the wafer W to the wafer placement surface 21. Next, the chamber is set to a reaction gas atmosphere at a predetermined pressure (for example, several tens to several hundreds of Pa), and in this state, an RF voltage is applied between an upper electrode (not shown) provided at a ceiling portion in the chamber and the base plate 30 of the wafer placement table 10 to generate plasma. A surface of the wafer W is processed by the generated plasma. A refrigerant is circulated through the refrigerant flow path 32 of the base plate 30 as appropriate. In processing the wafer W with plasma in this manner, heat input by the plasma is removed by the base plate 30, and the wafer placement surface 21 is controlled to a desired temperature.

Here, in processing the wafer W with plasma, due to heat input by the plasma, an upper portion of the wafer placement table 10 becomes high in temperature and a lower portion thereof becomes low in temperature. As a result, the wafer placement table 10 warps so as to be convex upward. That is, the wafer placement table 10 warps into a shape in which a center is high and becomes gradually lower toward an outer peripheral edge. Since the power feeding member 70 is located at a position offset from the center of the wafer placement table 10, as the wafer placement table 10 warps into the convex shape, the power feeding member 70 tilts obliquely with respect to a central axis of the wafer placement table 10.

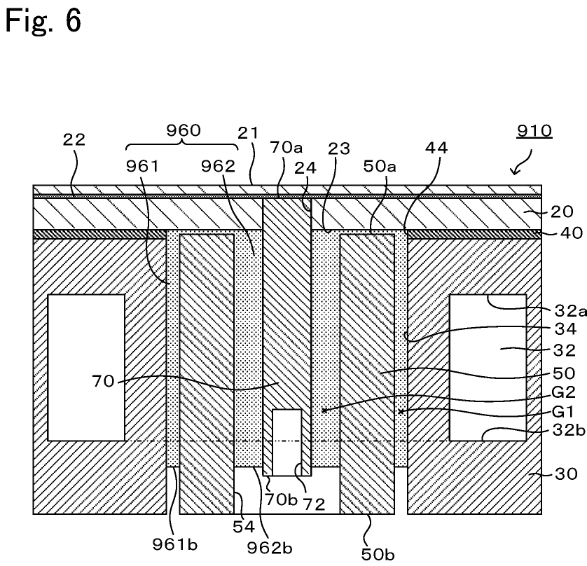

The inventor performed an analysis of an amount of displacement of a wafer placement table 910 shown in FIG. 6. The wafer placement table 910 is a comparative embodiment, in which a lower surface 961b of a first adhesive portion 961 and a lower surface 962b of a second adhesive portion 962 of an adhesive layer 960 are located below the bottom surface 32b of the refrigerant flow path 32. In FIG. 6, the same reference signs are assigned to the same components as those of the wafer placement table 10. When an upper portion of the wafer placement table 910 becomes high in temperature and a lower portion thereof becomes low in temperature, the wafer placement table 910 warps into a convex shape; as a result of analyzing the deformation amount at that time, it was found that the manner of deformation of the wafer placement table 910 differed with a plane including the bottom surface 32b of the refrigerant flow path 32 (two-dot chain line in FIG. 6) as a boundary. In the wafer placement table 910, the power feeding member 70 is fixed, by the second adhesive portion 962, down to below the bottom surface 32b of the refrigerant flow path 32, and the insulating tube 50 is fixed, by the first adhesive portion 961, down to below the bottom surface 32b of the refrigerant flow path 32. Therefore, when the manner of deformation of the wafer placement table 910 differs with the plane including the bottom surface 32b of the refrigerant flow path 32 as a boundary, both the power feeding member 70 and the insulating tube 50 change in the manner of deformation midway, and a shear force acts on a connection portion between the power feeding member 70 and the electrostatic electrode 22 due to the influence thereof. Since the connection portion between the power feeding member 70 and the electrostatic electrode 22 is not so strong in terms of strength, if such a shear force acts, the power feeding member 70 may come off from the electrostatic electrode 22.

In contrast, in the wafer placement table 10 of the present embodiment, the lower surface 62b of the second adhesive portion 62 of the adhesive layer 60 is located above the bottom surface 32b of the refrigerant flow path 32. That is, a portion of the power feeding member 70 below the bottom surface 32b of the refrigerant flow path 32 is not fixed by the second adhesive portion 62 and is in a free state. Therefore, even if the manner of deformation of the wafer placement table 10 differs with the plane including the bottom surface 32b of the refrigerant flow path 32 as a boundary when the wafer placement table 10 warps into a convex shape, the power feeding member 70 does not change in the manner of deformation midway. Accordingly, almost no shear force acts on the connection portion between the power feeding member 70 and the electrostatic electrode 22. Further, the lower surface 61b of the first adhesive portion 61 of the adhesive layer 60 is located above the bottom surface 32b of the refrigerant flow path 32. That is, a portion of the insulating tube 50 below the bottom surface 32b of the refrigerant flow path 32 is not fixed by the first adhesive portion 61 and is in a free state. Therefore, even if the manner of deformation of the wafer placement table 10 differs with the plane including the bottom surface 32b of the refrigerant flow path 32 as a boundary when the wafer placement table 10 warps into a convex shape, neither the insulating tube 50 nor the power feeding member 70 changes in the manner of deformation midway. Accordingly, almost no shear force acts on the connection portion between the power feeding member 70 and the electrostatic electrode 22.

As described above, in the wafer placement table 10 described in detail, when heat is input from the wafer placement surface 21 side, the wafer placement table 10 deforms so as to be convex upward. The manner of deformation of the wafer placement table 10 at this time differs between an upper side and a lower side with a plane including the bottom surface 32b of the refrigerant flow path 32 as a boundary. In the present embodiment, both the lower surface 61b of the first adhesive portion 61 and the lower surface 62b of the second adhesive portion 62 are located above the bottom surface 32b of the refrigerant flow path 32. Accordingly, even if the manner of deformation of the wafer placement table 10 differs between the upper side and the lower side with the plane including the bottom surface 32b of the refrigerant flow path 32 as a boundary, it is possible to suppress occurrence of a problem in the connection between the power feeding member 70 and the electrostatic electrode 22 due to the influence thereof.

Further, the absolute value of the difference in coefficient of thermal expansion between the ceramic plate 20 and the base plate 30 at 40 to 570° C is preferably 1.0ppm/K or less. This can suppress occurrence of a problem in the connection between the power feeding member 70 and the electrostatic electrode 22 due to a difference in thermal expansion between the ceramic plate 20 and the base plate 30.

Further, both the lower surface 61b of the first adhesive portion 61 and the lower surface 62b of the second adhesive portion 62 are located at the same height as, or below, the ceiling surface 32a of the refrigerant flow path 32. As a result, heat at a position immediately above the base-plate through hole 34 is more efficiently transferred to the refrigerant in the refrigerant flow path 32 via the first and second adhesive portions 61 and 62 than in a case where both the lower surface 61b of the first adhesive portion 61 and the lower surface 62b of the second adhesive portion 62 are located above the ceiling surface 32a of the refrigerant flow path 32. Accordingly, temperature uniformity of the wafer W is improved.

Further, in a plan view, the area S1 of the first gap G1 is smaller than the area S2 of the second gap G2. As a result, when bonding the insulating tube 50 with the adhesive 60x (see FIG. 5B), an amount by which the adhesive 60x climbs up is larger in the first gap G1 than in the second gap G2. Consequently, it is easy to form a structure in which the lower surface 62b of the second adhesive portion 62 is located above the lower surface 61b of the first adhesive portion 61.

Also, the lower surface 70b of the power feeding member 70 includes the socket portion 72 (connector) connectable to the tip end of the external cable 90 and is located above the lower surface 50b of the insulating tube 50, and the lower surface 62b of the second adhesive portion 62 is located above the lower surface 70b of the power feeding member 70. Therefore, the second adhesive portion 62 is less likely to adhere to the socket portion 72 on the lower surface 70b of the power feeding member 70.

Further, the thermal conductivity of the base plate 30 is preferably 50W/mK or more. Thus, heat of the wafer W is efficiently transferred to the refrigerant in the refrigerant flow path 32 via the base plate 30, thereby improving temperature uniformity of the wafer W. Further, the thermal conductivity of the adhesive layer 60 is preferably 0.5W/mK or more. Thus, heat at a position immediately above the base-plate through hole 34 is efficiently transferred to the refrigerant in the refrigerant flow path 32 via the adhesive layer 60 (the first and second adhesive portions 61 and 62), thereby improving temperature uniformity of the wafer W.

It should be noted that the present invention is not limited to the embodiment described above in any way, and it is needless to say that the present invention can be carried out in various modes as long as they fall within the technical scope of the present invention.

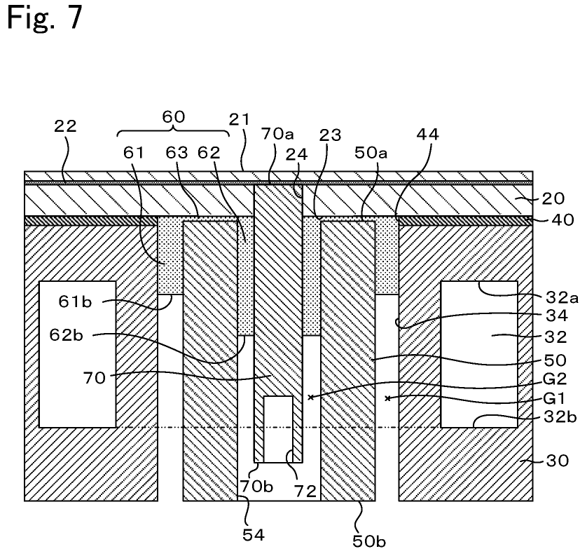

In the above-described embodiment, the example has been described in which the lower surface 62b of the second adhesive portion 62 is located above the lower surface 61b of the first adhesive portion 61; however, as shown in FIG. 7, the lower surface 61b of the first adhesive portion 61 may be located above the lower surface 62b of the second adhesive portion 62. In FIG. 7, the same reference signs are assigned to the same components as those of the above-described embodiment. In FIG. 7, in a plan view, the area of the first gap G1 is larger than the area of the second gap G2. As a result, when bonding the insulating tube 50 with the adhesive 60x (see FIG. 5B), an amount by which the adhesive 60x climbs up is larger in the second gap G2 than in the first gap G1. Consequently, it is easy to form the structure of FIG. 7 in which the lower surface 61b of the first adhesive portion 61 is located above the lower surface 62b of the second adhesive portion 62.

In the above-described embodiment, both the lower surface 61b of the first adhesive portion 61 and the lower surface 62b of the second adhesive portion 62 are located above the bottom surface 32b of the refrigerant flow path 32; however, it is sufficient that at least one of the lower surface 61b of the first adhesive portion 61 or the lower surface 62b of the second adhesive portion 62 is located above the bottom surface 32b of the refrigerant flow path 32.

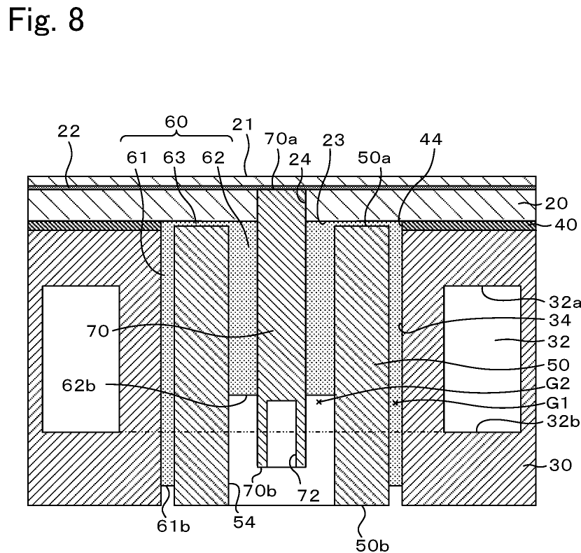

For example, if the lower surface 62b of the second adhesive portion 62 is located at the same height as, or above, the bottom surface 32b of the refrigerant flow path 32, the lower surface 61b of the first adhesive portion 61 may be at the same height as the bottom surface 32b of the refrigerant flow path 32 or may be located below the same. One example thereof is shown in FIG. 8. In FIG. 8, the same reference signs are assigned to the same components as those of the above-described embodiment. As shown in FIG. 8, if the lower surface 62b of the second adhesive portion 62 is located at the same height as, or above, the bottom surface 32b of the refrigerant flow path 32, a portion of the power feeding member 70 below the bottom surface 32b of the refrigerant flow path 32 is not fixed by the second adhesive portion 62 of the adhesive layer 60 and is in a free state. Therefore, even if the portion of the insulating tube 50 below the bottom surface 32b of the refrigerant flow path 32 is fixed by the first adhesive portion 61, the power feeding member 70 only deforms in association with deformation above the plane including the bottom surface 32b of the refrigerant flow path 32 in the wafer placement table 10. That is, even if the wafer placement table is warped into a convex shape due to an upper portion being high in temperature and a lower portion being low in temperature, the power feeding member 70 does not change in the manner of deformation midway. Accordingly, almost no shear force acts on the connection portion between the power feeding member 70 and the electrostatic electrode 22.

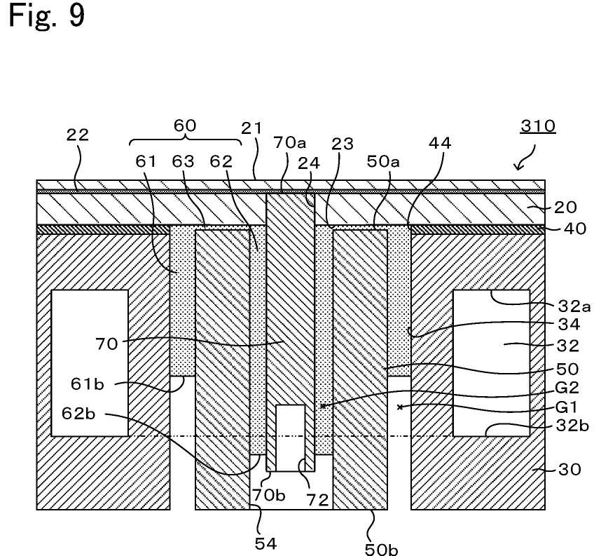

Alternatively, if the lower surface 61b of the first adhesive portion 61 is located at the same height as, or above, the bottom surface 32b of the refrigerant flow path 32, the lower surface 62b of the second adhesive portion 62 may be at the same height as the bottom surface 32b of the refrigerant flow path 32 or may be located below the same. One example thereof is shown in FIG. 9. In FIG. 9, the same reference signs are assigned to the same components as those of the above-described embodiment. As shown in FIG. 9, if the lower surface 61b of the first adhesive portion 61 is located at the same height as, or above, the bottom surface 32b of the refrigerant flow path 32, a portion of the insulating tube 50 below the bottom surface 32b of the refrigerant flow path 32 is not fixed by the first adhesive portion 61 and is in a free state. Therefore, even if a portion of the power feeding member 70 below the bottom surface 32b of the refrigerant flow path 32 is fixed by the second adhesive portion 62, the insulating tube 50 integrated with the power feeding member 70 and the second adhesive portion 62 deforms only in association with deformation above the plane including the bottom surface 32b of the refrigerant flow path 32 in the wafer placement table 10. That is, even if the wafer placement table is warped into a convex shape due to an upper portion being high in temperature and a lower portion being low in temperature, neither the insulating tube 50 nor the power feeding member 70 changes in the manner of deformation midway. Accordingly, almost no shear force acts on the connection portion between the power feeding member 70 and the electrostatic electrode 22.

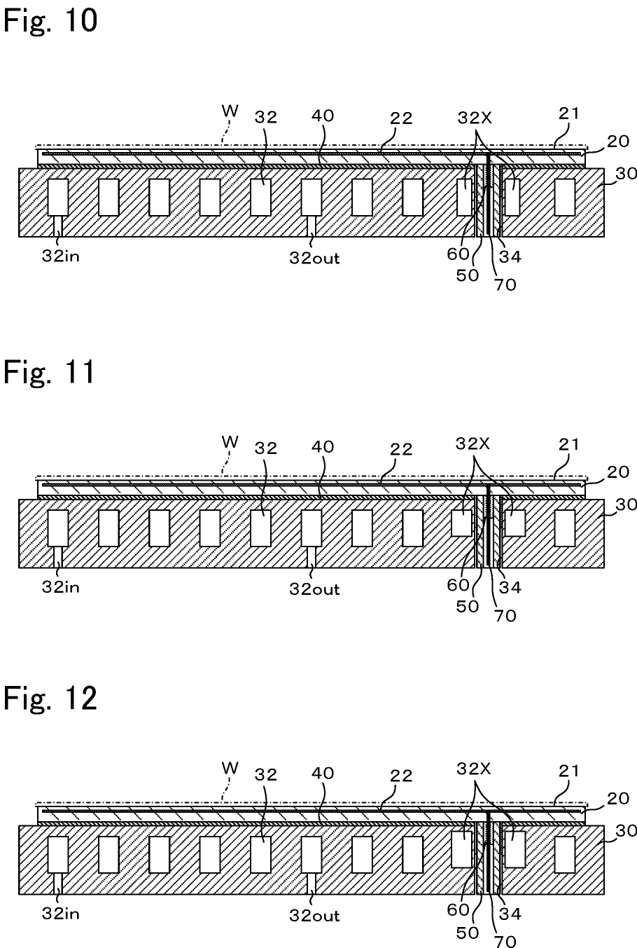

In the above-described embodiment, the shape of the refrigerant flow path 32 is not particularly changed between the peripheral region of the baseplate through hole 34 and the region deviating therefrom; however, it may be changed. For example, in the peripheral region of the baseplate through hole 34, the cross-sectional area of the refrigerant flow path 32 may be reduced as compared with the region deviating therefrom. This increases a flow velocity of the refrigerant flowing through the peripheral region of the baseplate through hole 34 in the refrigerant flow path 32. Accordingly, heat at a position immediately above the baseplate through hole 34 is efficiently transferred to the refrigerant in the refrigerant flow path 32, thereby improving temperature uniformity of the wafer W. In reducing the cross-sectional area of the refrigerant flow path 32, when the cross section of the refrigerant flow path 32 is rectangular, as shown in FIG. 10, a width (a length in a horizontal direction) of a refrigerant flow path 32X passing through the peripheral region of the baseplate through hole 34 may be shortened as compared with a width of the refrigerant flow path 32 passing through the region deviating therefrom. Alternatively, as shown in FIG. 11, a height (a length in the up-down direction) of the refrigerant flow path 32X passing through the peripheral region of the baseplate through hole 34 may be shortened as compared with a height of the refrigerant flow path 32 passing through the region deviating therefrom. In FIGS. 10 and 11, the same reference signs are assigned to the same components as those of the above-described embodiment.

In the above-described embodiment, a height from the ceiling surface of the refrigerant flow path 32 to the wafer placement surface 21 is not particularly changed between the peripheral region of the base-plate through hole 34 and the region deviating therefrom; however, it may be changed. For example, as shown in FIG. 12, a distance from the ceiling surface of the refrigerant flow path 32X passing through the peripheral region of the base-plate through hole 34 to the wafer placement surface 21 may be shorter than a distance from the ceiling surface of the refrigerant flow path 32 passing through the region deviating therefrom to the wafer placement surface 21. Accordingly, heat at a position immediately above the base-plate through hole 34 is efficiently transferred to the refrigerant in the refrigerant flow path 32, thereby improving temperature uniformity of the wafer W. In FIG. 12, the same reference signs are assigned to the same components as those of the above-described embodiment.

In the above-described embodiment, both the lower surface 61b of the first adhesive portion 61 and the lower surface 62b of the second adhesive portion 62 are located below the ceiling surface 32a of the refrigerant flow path 32; however, one or both of the lower surface 61b of the first adhesive portion 61 and the lower surface 62b of the second adhesive portion 62 may be located above the ceiling surface 32a of the refrigerant flow path 32. However, in view of temperature uniformity of the wafer W, the above-described embodiment is preferable.

In the above-described embodiment, an example has been described in which the lower surface 70b of the power feeding member 70 is located above the lower surface 50b of the insulating tube 50; however, the present invention is not limited thereto. For example, the lower surface 70b of the power feeding member 70 may be located at the same height as, or below, the lower surface 50b of the insulating tube 50, or may be located at the same height as, or below, a lower surface of the base plate 30.

In the above-described embodiment, the socket portion 72 is provided on the lower surface 70b of the power feeding member 70 and the plug 92 is provided at the tip end of the external cable 90; however, the present invention is not limited thereto. For example, a plug may be provided on the lower surface 70b of the power feeding member 70 and a socket may be provided at the tip end of the external cable 90. Alternatively, the lower surface 70b of the power feeding member 70 may be formed into a recessed shape, and the tip end of the external cable 90 may be brought into elastic contact with this lower surface 70b.

In the above-described embodiment, a metal layer is exemplified as the bonding layer 40; however, the present invention is not limited thereto. For example, a resin layer or an inorganic adhesive may be employed as the bonding layer 40. Examples of a material of the resin layer include insulating resins such as an epoxy resin, an acrylic resin, and a silicone resin. The bonding layer 40 may be obtained by adding a filler to an insulating resin. The filler preferably has a higher thermal conductivity than the insulating resin of the bonding layer 40 and may be, for example, alumina or aluminum nitride. When employing a bonding layer having good thermal conductivity, it is preferable that the bonding layer is a metal bonding layer.

In the above-described embodiment, the ceramic plate 20 incorporates the electrostatic electrode 22; however, the present invention is not limited thereto. For example, instead of or in addition to the electrostatic electrode 22, the ceramic plate 20 may incorporate a heater electrode (resistance heating element) or may incorporate an electrode for plasma generation (RF electrode).

What is claimed is:

1. A member for semiconductor manufacturing apparatus comprising:
a ceramic plate having a wafer placement surface on its upper surface and incorporating an electrode;
a base plate provided on a lower surface of the ceramic plate and incorporating a refrigerant flow path;
a base-plate through hole penetrating the base plate in an up-down direction at a position offset from a center of the base plate;
an insulating tube inserted into the base-plate through hole;
a power feeding member inserted into the insulating tube and having a tip electrically connected to the electrode; and
an adhesive layer having a first adhesive portion provided in a first gap between the insulating tube and the base-plate through hole and a second adhesive portion provided in a second gap between the insulating tube and the power feeding member,
wherein a lower surface of the power feeding member is located below a bottom surface of the refrigerant flow path, and
at least one of a lower surface of the first adhesive portion or a lower surface of the second adhesive portion is located at the same height as, or above, the bottom surface of the refrigerant flow path.

2. The member for semiconductor manufacturing apparatus according to claim 1, wherein an absolute value of a difference in coefficient of thermal expansion between the ceramic plate and the base plate at 40 to 570 °C is 1.0ppm/K or less.

3. The member for semiconductor manufacturing apparatus according to claim 1, wherein the lower surface of the first adhesive portion and the lower surface of the second adhesive portion are both located at the same height as, or below, a ceiling surface of the refrigerant flow path.

4. The member for semiconductor manufacturing apparatus according to claim 1, wherein the lower surface of the first adhesive portion and the lower surface of the second adhesive portion are both located at the same height as, or above, the bottom surface of the refrigerant flow path.

5. The member for semiconductor manufacturing apparatus according to claim 1, wherein, in a plan view, an area of the first gap is smaller than an area of the second gap.

6. The member for semiconductor manufacturing apparatus according to claim 1, wherein the lower surface of the power feeding member includes a connector connectable to a tip end of an external cable and is located above a lower surface of the insulating tube, and the lower surface of the second adhesive portion is located above the lower surface of the power feeding member.

7. The member for semiconductor manufacturing apparatus according to claim 1, wherein a thermal conductivity of the base plate is 50 W/mK or more.

8. The member for semiconductor manufacturing apparatus according to claim 1, wherein thermal conductivity of the first and second adhesive portions is 0.5 W/mK or more.

9. The member for semiconductor manufacturing apparatus according to claim 1, wherein a cross-sectional area of the refrigerant flow path is smaller in a peripheral region of the base-plate through hole than in a region deviating from the peripheral region of the base-plate through hole.

10. The member for semiconductor manufacturing apparatus according to claim 1, wherein a distance from the wafer placement surface to a ceiling surface of the refrigerant flow path is shorter in a peripheral region of the base-plate through hole than in a region deviating from the peripheral region of the base-plate through hole.
